(19) United States
(12) Patent Application Publication
(10) Pub. No.: US 2024/0203746 A1
(43) Pub. Date: Jun. 20, 2024

(54) CHEMICAL ETCHING METHOD USING A METAL CATALYST

(71) Applicants: SEMES CO., LTD., Chungcheongnam-do (KR); UIF (University Industry Foundation), Yonsei University, Seoul (KR)

(72) Inventors: Hang Lim LEE, Chungcheongnam-do (KR); Min Young KIM, Gyeonggi-do (KR); Jung Woo OH, Incheon (KR); Kyung Hwan KIM, Incheon (KR); Sun Hae CHOI, Incheon (KR)

(21) Appl. No.: 18/391,618

(22) Filed: Dec. 20, 2023

(30) Foreign Application Priority Data
Dec. 20, 2022 (KR) 10-2022-0179705

(51) Int. Cl. H01L 21/306

(52) U.S. Cl. CPC H01L 21/30604

(57) ABSTRACT

A chemical etching method using a metal catalyst is provided that prevents deterioration of device performance by preventing the formation of deep-level impurities inside silicon. The etching method comprises forming a metal catalyst containing nickel silicide on a silicon substrate, and selectively etching the silicon substrate in contact with the metal catalyst through chemical etching of the metal catalyst.

This application claims the benefit of Korean Patent Application No. 10-2022-0179705, filed on Dec. 20, 2022, in the Korean Intellectual Property Office, the disclosure of which is incorporated herein by reference in its entirety.

### BACKGROUND

### 1. Field

The present invention relates to a chemical etching method using a metal catalyst.

### 2. Description of the Related Art

Silicon (Si)-based micro structures and nano structures are used in devices in the fields of electronics, optoelectronics, energy conversion and storage, including the semiconductor industry, and have recently been applied to bio-chemical sensors and catalysts.

To manufacture micro or nano structures, various methods such as Reactive Ion Etching (RIE) and Metal Assisted Chemical Etching (MACE, MACetch, or metal-catalyzed chemical etching) can be used.

Here, unlike other methods, metal catalyst chemical etching can produce micro or nano structures in a top-down manner. In addition, metal catalyst chemical etching is a simple process and exhibits anisotropic etching characteristics. In addition, since crystal damage and/or plasma damage are not formed on the surface of silicon, defects on the silicon surface caused by etching can be minimized.

### SUMMARY

Meanwhile, metal catalyst chemical etching is a method, in which a metal catalyst is formed on a silicon substrate, and then etching is performed using an etching solution, and the silicon substrate in contact with the metal catalyst is etched. The metals mainly used as metal catalysts are noble metals such as gold (Au) and silver (Ag). However, noble metals such as gold and silver are difficult to introduce into the CMOS (Complementary Metal Oxide Semiconductor) process. This is because, after chemical etching, part of the metal catalyst acts as a deep-level impurity inside the silicon in contact with the metal catalyst, becoming a factor that degrades device performance.

The problem to be solved by the present invention is to provide a chemical etching method using a metal catalyst that prevents deterioration of device performance by preventing the formation of deep-level impurities inside silicon.

The objects of the present invention are not limited to the problems mentioned above, and other objects not mentioned will be clearly understood by those skilled in the art from the description below.

One aspect of the etching method of the present invention for achieving the above object comprises forming a metal catalyst containing nickel silicide on a silicon substrate, and selectively etching the substrate in contact with the metal catalyst through chemical etching of the metal catalyst.

Another aspect of the etching method of the present invention comprises forming nickel on a silicon substrate with a thickness of 10 nm to 30 nm, heat treating the silicon substrate, on which the nickel is formed, at a temperature of 300 to 600° C. to form a metal catalyst containing nickel silicide with a thickness of 20 nm to 70 nm, and selectively etching the silicon substrate in contact with the metal catalyst by reacting the silicon substrate, on which the metal catalyst is formed, with an etching solution containing H2O2 and HF.

Still another aspect of the etching method of the present invention comprises forming a metal catalyst containing nickel on a silicon substrate, wherein a thickness of the nickel is 3 nm or less, and selectively etching the silicon substrate in contact with the metal catalyst through chemical etching of the metal catalyst.

Specific details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIGS. 1 to 3 are intermediate drawings for explaining an etching method according to some embodiments of the present invention;

FIG. 4 is a diagram for explaining the chemical etching process of FIG. 3;

FIG. 5 is an intermediate drawing for explaining an etching method according to some embodiments of the present invention;

FIGS. 6 and 7 are intermediate drawings for explaining an etching method according to some embodiments of the present invention;

FIG. 8 is a diagram for explaining the results of etching a silicon substrate using a metal catalyst containing nickel silicide; and

FIG. 9 is a diagram for explaining the results of etching a silicon substrate using a metal catalyst containing nickel silicide containing platinum.

### DETAILED DESCRIPTION

Hereinafter, preferred embodiments of the present invention will be described in detail with reference to the attached drawings. The advantages and features of the present invention and methods for achieving them will become clear by referring to the embodiments described in detail below along with the accompanying drawings. However, the present invention is not limited to the embodiments disclosed below and may be implemented in various different forms. The present embodiments are merely intended to ensure that the disclosure of the present invention is complete and to full inform those skilled in the technical field to which the present invention pertains on the scope of the invention, and the present invention is only defined by the scope of the claims. Like reference numerals refer to like elements throughout the specification.

Spatially relative terms such as “below,” “beneath,” “lower,” “above,” “upper,” etc. can be used to easily describe the correlation between one elements or components and other elements or components. Spatially relative terms should be understood as terms that include different directions of the element during use or operation in addition to the direction shown in the drawings. For example, if an element shown in the drawings is turned over, an element described as “below” or “beneath” another element may be placed “above” the other element. Accordingly, the illustrative term “below” may include both downward and upward directions. Elements can also be oriented in other directions, so spatially relative terms can be interpreted according to orientation.

Although first, second, etc. are used to describe various components, elements and/or sections, it is understood that these components, elements and/or sections are not limited by these terms. These terms are merely used to distinguish one component, element, or section from other components, elements, or sections. Therefore, the first component, first element, or first section mentioned below may also be a second component, second element, or second section within the technical spirit of the present invention.

Hereinafter, embodiments of the present invention will be described in detail with reference to the accompanying drawings. In the description with reference to the accompanying drawings, identical or corresponding components will be assigned the same reference numbers regardless of the reference numerals, and the redundant explanation for this will be omitted.

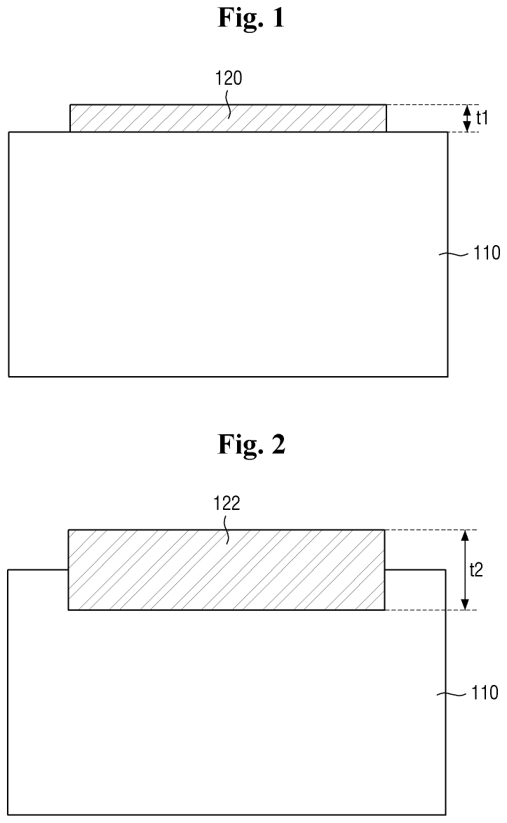

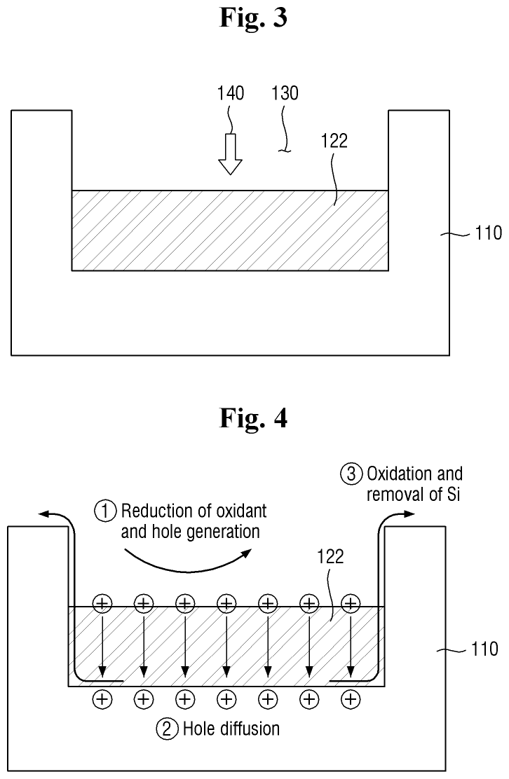

FIGS. 1 to 3 are intermediate drawings for explaining an etching method according to some embodiments of the present invention. FIG. 4 is a diagram for explaining the chemical etching process of FIG. 3.

Referring to FIG. 1, nickel 120 is formed on a silicon substrate 110.

Specifically, the silicon substrate 110 may be an n-type substrate or a p-type substrate.

The thickness t1 of nickel 120 may be 10 nm to 30 nm (i.e., the thickness equal to or greater than 10 nm and equal to or less than 30 nm), but is not limited thereto.

Methods for forming patterned nickel 120 may vary.

For example, photoresist is formed on the silicon substrate 110 by spin coating.

Next, a lithography process is performed to pattern the photoresist. The lithography process may be performed by in the order of, for example, shadow mask formation, light exposure (UV exposure), and development.

Next, a nickel layer is formed on the silicon substrate 110 on which the patterned photoresist is formed. Accordingly, part of the nickel layer is formed on the upper surface of the patterned photoresist, and the other part is formed on the exposed silicon substrate 110 between adjacent photoresists. Nickel 120 shown in FIG. 1 corresponds to a portion of the nickel layer formed on the exposed silicon substrate 110. Methods for forming the nickel layer may comprise, but are not limited to, sputtering, CVD (Chemical Vapor Deposition), PVD (Physical Vapor Deposition), ALD (Atomic Layer Deposition), and E-beam evaporation.

Referring to FIG. 2, the silicon substrate 110 on which nickel 120 is formed is heat treated to form nickel silicide (i.e., metal catalyst 122).

Specifically, through heat treatment, nickel 120 and the silicon substrate 110 react to form nickel silicide. Heat treatment may comprise, for example, performing rapid thermal processing (RTP) at a temperature of 300° C. to 600° C. for 10 to 60 seconds. By performing RTP at a temperature of 300° C. to 600° C., NiSi can be mainly formed. When RTP is performed at a temperature of 300° C. or lower, a relatively large amount of Ni₂Si is formed, and when RTP is performed at a temperature of 600° C. or higher, a relatively large amount of NiSi₂ is formed. NiSi has a smaller sheet resistance than Ni₂Si and NiSi₂, so it is a relatively stable material. Therefore, if NiSi is used, chemical etching, which will be explained later, can be carried out stably.

The thickness t2 of nickel silicide (i.e., metal catalyst 122) may be 20 nm to 70 nm, but is not limited thereto.

Referring to FIG. 3, chemical etching is performed by reacting an etching solution with the silicon substrate 110 on which the metal catalyst 122 is formed.

Specifically, the etching solution includes an oxidizing agent and an acid. The oxidizing agent is used to react with the metal catalyst 122 to form holes, and the acid is used to etch the silicon substrate 110 in contact with the metal catalyst 122. In some embodiments, H₂O₂ or KMnO₄ may be used as the oxidizing agent, and HF may be used as the acid, but is not limited thereto.

The silicon substrate 110 in contact with the metal catalyst 122 is selectively etched by the etching solution, and the metal catalyst 122 is moved in the downward direction 140. Accordingly, a trench (or micro structure or nano structure) 130 is formed in the silicon substrate 110.

Optionally, after etching the silicon substrate 110, the metal catalyst 122 remaining on the silicon substrate 110 may be removed.

Here, using FIG. 4, the chemical etching process using the metal catalyst 122 will be described in detail.

Referring to FIG. 4, the oxidizing agent in the etching solution reacts with the metal catalyst 122 (see reference numeral \textcircled{1}). The oxidizing agent is reduced by taking electrons from the metal catalyst 122. Accordingly, holes are formed in the metal catalyst 122.

The formed holes are injected and diffused into the silicon substrate 110 (see reference numeral \textcircled{2}). Accordingly, the area of the silicon substrate 110 in contact with the metal catalyst 122 is oxidized.

The oxidized area on the silicon substrate 110 is removed by acid in the etching solution (see reference numeral \textcircled{3}).

In summary, a micro structure can be formed in a top-down manner through chemical etching of the metal catalyst 122. Despite being a wet process using an etching solution, anisotropic etching characteristics appear.

Additionally, when nickel silicide is used as the metal catalyst 122, deep-level impurities are not formed in the silicon substrate 110 by the etching process. Therefore, device performance can be prevented from being impaired.

Unlike the above, only an acid (e.g., HF) may be used as an etching solution, excluding an oxidizing agent. Etching of the silicon substrate 110 may proceed even without using an oxidizing agent.

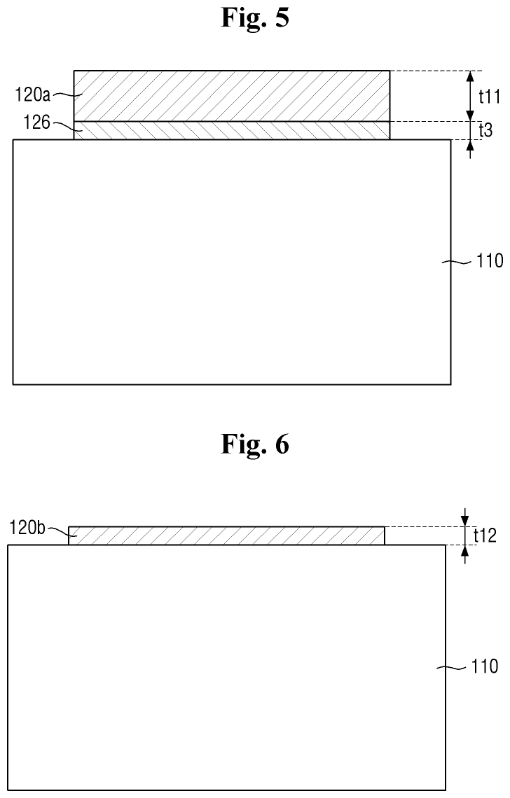

FIG. 5 is an intermediate drawing for explaining an etching method according to some embodiments of the present invention. For convenience of explanation, differences from those described using FIGS. 1 to 4 will be mainly explained.

In the etching method described using FIGS. 1 to 4, nickel silicide is used as the metal catalyst 122. In the etching method to be described using FIG. 5, nickel silicide (i.e., PtNiSi) containing platinum (Pt) is used as the metal catalyst 122.

As shown in FIG. 5, platinum (Pt) 126 and nickel (Ni) 120a are stacked on the silicon substrate 110.

Platinum 126 is formed on the silicon substrate 110 with a thickness t3, and nickel 120a is formed on the platinum 126 with a thickness t11. Platinum 126 is formed thinner than nickel 120a. For example, the thickness t3 of platinum 126 may be ⅙ to 1/7 of the thickness t11 of nickel 120a, but is not limited thereto. For example, the thickness t3 may be 1 nm to 3 nm, and the thickness t11 may be 5 nm to 25 nm.

Alternatively, nickel may first be formed on the silicon substrate 110 and then platinum may be formed thereon.

Alternatively, a nickel-platinum alloy may be stacked on the silicon substrate 110 and then heat treated.

Next, the silicon substrate 110, on which platinum 126 and nickel 120a are formed, is heat treated to form nickel silicide containing platinum.

Next, chemical etching is performed by reacting an etching solution on the silicon substrate 110, on which nickel silicide containing platinum is formed.

Meanwhile, the etching rate when nickel silicide containing platinum is used as a metal catalyst can be significantly faster than the etching rate when nickel silicide is used as a metal catalyst. For example, it can be more than 10 times faster. For example, when nickel silicide is used as a metal catalyst, the etching rate may be about 30 to 40 nm/min, and when platinum-containing nickel silicide is used as a metal catalyst, the etching rate may be 400 to 600 nm/min.

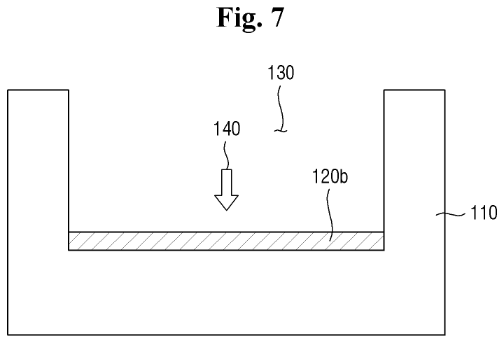

FIGS. 6 and 7 are intermediate drawings for explaining an etching method according to some embodiments of the present invention. For convenience of explanation, differences from those described using FIGS. 1 to 4 will be mainly explained.

In the etching method to be described using FIGS. 1 to 4, nickel silicide (i.e., NiSi) is used as the metal catalyst 122. In the etching method described using FIGS. 6 and 7, ultrathin nickel is used as the metal catalyst 122.

Referring to FIG. 6, nickel 120b with a thickness t12 is formed on the silicon substrate 110. The thickness (t12) may be 3 nm or less, and specifically may be 0.01 nm or more and 3 nm or less. The thickness (t12) may preferably be 1 nm to 2 nm, and more preferably 1 nm to 1.5 nm.

Next, as shown in FIG. 7, ultrathin nickel 120b is used as a metal catalyst. Chemical etching is performed by reacting an etching solution on the silicon substrate 110 on which the metal catalyst is formed.

When thin nickel 120b of 3 nm or less is used as a metal catalyst, chemical etching is possible more stably than when thick nickel (i.e., nickel thicker than 3 nm) is used as a metal catalyst. If the nickel 120b is very thin, the entire area of the nickel 120b is in an oxidized state, thereby improving chemical stability. Therefore, nickel 120b can survive the etching solution for a longer period of time. Therefore, if ultrathin nickel 120b is used as a metal catalyst, a deeper trench can be formed. For example, during the same etching time, if 3 nm or less thin nickel 120b is used as a metal catalyst, a trench can be formed to a depth of 500 nm or more, but if 5 nm thick nickel is used as a metal catalyst, a trench can be formed to a depth of 200 nm or less.

In addition, if thin nickel 120b of 3 nm or less is used as a metal catalyst, the surface of the trench is formed smoothly (i.e., smooth surface), but if thick nickel (e.g., nickel thicker than 3 nm) is used as a metal catalyst, the trench surface is formed rough (i.e., rough surface).

If the thickness of nickel 120b is thinner than 0.01 nm, it becomes difficult to effectively function as a metal catalyst.

Additionally, if thin nickel 120b with a thickness of 1 nm to 2 nm is used, the chemical stability of nickel 120b is guaranteed, and wet etching can be performed stably.

Below, etching methods according to some embodiments of the present invention will be described using representative examples. However, the etching method according to some embodiments of the present invention is not limited to the method illustrated below.

### 1. METHOD OF ETCHING A SILICON SUBSTRATE USING A METAL CATALYST CONTAINING NICKEL SILICIDE

### Experimental Example 1

An n-type silicon substrate was prepared. The silicon substrate has a crystal orientation of (100) and a resistance value of 1 to 10 Ω·cm. Next, 15 nm of nickel was formed on the silicon substrate using electron beam deposition. Next, the silicon substrate was heat treated using the RTP method and performed at a temperature of 500° C. for 30 seconds. As a result of heat treatment, nickel silicide (metal catalyst) was formed on the silicon substrate. Chemical etching was performed by reacting an etching solution containing HF and H₂O₂ (HF/H₂O₂/H₂O) on the silicon substrate on which nickel silicide was formed. At this time, the etching times were 15 minutes, 30 minutes, 45 minutes, and 60 minutes.

### Experimental Example 2

It is the same as Experimental Example 1, except that a p-type silicon substrate (crystal direction is (100), resistance value is 5 to 10 Ω·cm) is used.

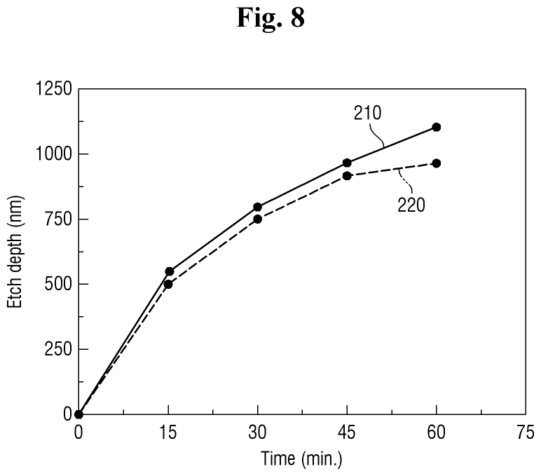

The results of the above experimental examples are summarized in FIG. 8 and Table 1. FIG. 8 and Table 1 show the change in etching depth according to etching time.

TABLE 1

| | | 15 minutes | | 30 minutes | | 45 minutes | | 60 minutes | |
|---|---|---|---|---|---|---|---|---|---|
| Experimental | Etching Depth | 0.525 | μm | 0.794 | μm | 0.962 | μm | 1.10 | μm |
| Example 1 | Etching Rate | 35 | nm/min | 26.47 | nm/min | 21.38 | nm/min | 18.33 | nm/min |
| Experimental | Etching Depth | 0.488 | μm | 0.750 | μm | 0.919 | μm | 0.962 | μm |
| Example 2 | Etching Rate | 32.53 | nm/min | 25 | nm/min | 20.42 | nm/min | 16.03 | nm/min |

In FIG. 8, the x-axis represents etching time, and the y-axis represents etching depth. Reference numeral 210 corresponds to Experimental Example 1 (using an n-type silicon substrate), and reference numeral 220 corresponds to Experimental Example 2 (using a p-type silicon substrate).

Referring to FIG. 8 and Table 1, it can be seen that based on the same etching time, the etching amount on the n-type silicon substrate is greater than the etching amount on the p-type silicon substrate. For example, when the etching time was 15 minutes, a trench with an etching depth of 0.525 μm was formed on the n-type substrate, but a trench with an etch depth of 0.488 μm was formed on the p-type substrate. When the etching time was 60 minutes, a trench with an etching depth of 1.10 μm was formed on the n-type substrate, but a trench with an etching depth of 0.962 μm was formed on the p-type substrate.

As the etching time became longer, the etching rate on the n-type substrate and the etching rate on the p-type substrate gradually decreased. Referring to reference numerals 210 and 220, it can be seen that the slope gradually decreases as the etching time passes.

When the etching time was not long, there was no significant difference between the etching amount on the n-type substrate and the etching amount on the p-type substrate. On the other hand, as the etching time became longer (refer to 60 minutes), the difference between the etching amount on the n-type substrate and the etching amount on the p-type substrate widened somewhat.

### 2. METHOD OF ETCHING A SILICON SUBSTRATE USING A METAL CATALYST CONTAINING NICKEL SILICIDE CONTAINING PLATINUM

### (Experimental Example 3

It is the same as Experimental Example 1, except that instead of forming 15 nm of nickel on the silicon substrate, 2 nm of platinum (Pt) and 13 nm of nickel (Ni) are formed on the n-type silicon substrate. That is, nickel silicide containing platinum was used as a metal catalyst.

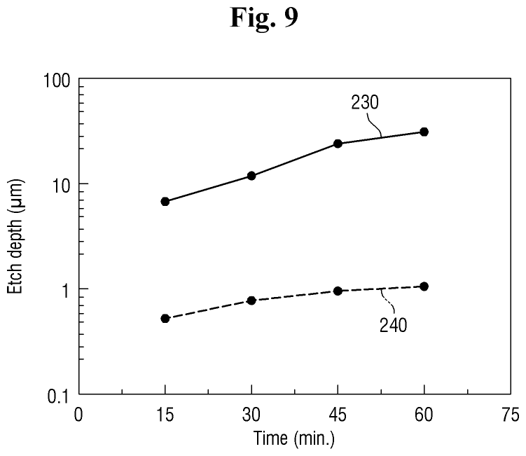

The results of the above experimental example are summarized in FIG. 9 and Table 2. FIG. 9 and Table 2 show changes in etching depth and etching rate according to etching time.

TABLE 2

| | | 15 minutes | | 30 minutes | | 45 minutes | | 60 minutes | |
|---|---|---|---|---|---|---|---|---|---|
| Experimental | Etching Depth | 0.525 | μm | 0.794 | μm | 0.962 | μm | 1.10 | μm |
| Example 1 | Etching Rate | 35 | nm/min | 26.47 | nm/min | 21.38 | nm/min | 18.33 | nm/min |
| Experimental | Etching Depth | 6.60 | μm | 12.2 | μm | 24.3 | μm | 32.6 | μm |
| Example 3 | Etching Rate | 440 | nm/min | 407 | nm/min | 540 | nm/min | 543 | nm/min |

| | | | | | | | | |
|---|---|---|---|---|---|---|---|---|
| Etching Rate Ratio | 12.57 | times | 15.37 | times | 25.26 | times | 29.64 | times |

(Experimental Example 3/
Experimental Example 1)

In FIG. 9, the x-axis represents the etching time, and the y-axis represents the etching depth. Reference numeral 240 corresponds to Experimental Example 1 (using NiSi as a metal catalyst and an n-type substrate), and reference numeral 230 corresponds to Experimental Example 2 (using PtNiSi as a metal catalyst and an n-type substrate).

Referring to FIG. 9 and Table 2, it can be seen that based on the same etching time, the etching amount using PtNiSi is greater than the etching amount using NiSi. For example, when the etching time was 15 minutes, a trench with an etching depth of 0.525 μm was formed when using NiSi, and a trench with an etching depth of 6.60 μm was formed when using PtNiSi.

It can be seen that the etching rate when using PtNiSi is more than 10 times improved than the etching rate when using NiSi. For example, when the etching time is 15 minutes, the etching rate when using NiSi is 35 nm/min, and the etching rate when using PtNiSi is 440 nm/min.

It can be seen that the etching rate when using PtNiSi as a metal catalyst is improved compared to the etching rate when using NiSi as a metal catalyst.

### 3. METHOD OF ETCHING A SILICON SUBSTRATE USING A METAL CATALYST CONTAINING ULTRATHIN NICKEL

### Experimental Example 4

A p-type silicon substrate was prepared. Next, 1 nm of nickel (metal catalyst) was formed on the silicon substrate. Chemical etching was performed by reacting an etching solution containing HF and H₂O₂ (HF/H₂O₂/H₂O) on a silicon substrate on which 1 nm of nickel was formed. At this time, the etching time was 15 minutes.

### Experimental Example 5

It is the same as Experimental Example 4, except that the thickness of nickel (metal catalyst) was formed to 5 nm.

In Experimental Example 4, a trench with an etching depth of 537 nm was formed, and in Experimental Example 5, a trench with an etching depth of 160 nm was formed. Based on an etching time of 15 minutes, in Experimental Example 4, the etching rate was 35.8 nm/min, and in Experimental Example 5, the etching rate was 10.67 nm/min.

It can be seen that the etching rate when using 1 nm nickel as a metal catalyst is approximately 3.36 times faster than the etching rate when using 5 nm nickel as a metal catalyst.

In other words, it was confirmed that the etching rate was improved when ultrathin nickel was used as a metal catalyst.

Although embodiments of the present invention have been described with reference to the above and the attached drawings, those skilled in the art will understand that the present invention can be implemented in other specific forms without changing the technical idea or essential features. Therefore, the embodiments described above should be understood in all respects as illustrative and not restrictive.

What is claimed is:

1. An etching method comprising:
forming a metal catalyst containing nickel silicide on a silicon substrate, and
selectively etching the silicon substrate in contact with the metal catalyst through chemical etching of the metal catalyst.

2. The etching method of claim 1, wherein forming the metal catalyst comprises,
forming nickel on the silicon substrate,
forming nickel silicide by heat treating the silicon substrate, on which the nickel is formed.

3. The etching method of claim 2, wherein the heat treating comprises performing rapid thermal processing (RTP) at a temperature of 300° C. to 600° C.

4. The etching method of claim 2, wherein the nickel is formed with a thickness of 10 nm to 30 nm, and the nickel silicide is formed with a thickness of 20 nm to 70 nm.

5. The etching method of claim 1, wherein the metal catalyst is nickel silicide containing platinum (Pt).

6. The etching method of claim 5, wherein forming the metal catalyst comprises,
stacking platinum and nickel on the silicon substrate,
heat treating the silicon substrate, on which the platinum and nickel are formed, to form nickel silicide containing platinum.

7. The etching method of claim 6, wherein stacking the platinum and nickel on the silicon substrate comprises,
forming platinum with a first thickness on the silicon substrate,
forming nickel with a second thickness on the platinum,
wherein the first thickness is smaller than the second thickness.

8. The etching method of claim 7, wherein the first thickness is ⅙ to 1/7 of the second thickness.

9. The etching method of claim 1 further comprises,
removing the metal catalyst remaining on the silicon substrate after etching the silicon substrate.

10. The etching method of claim 1, wherein the chemical etching uses an etching solution,
wherein the etching solution comprises an oxidizing agent for reacting with the metal catalyst to form a hole, and an acid for etching the silicon substrate in contact with the metal catalyst.

11. The etching method of claim 10, wherein the oxidizing agent is H₂O₂ or KMnO₄ and the acid is HF.

12. The etching method of claim 1, wherein the chemical etching uses an etching solution,
wherein the etching solution comprises an acid for etching a silicon substrate in contact with the metal catalyst.

13. An etching method comprising:
forming nickel on a silicon substrate with a thickness of 10 nm to 30 nm,
heat treating the silicon substrate, on which the nickel is formed, at a temperature of 300 to 600° C. to form a metal catalyst containing nickel silicide with a thickness of 20 nm to 70 nm, and
selectively etching the silicon substrate in contact with the metal catalyst by reacting the silicon substrate, on which the metal catalyst is formed, with an etching solution containing H₂O₂ and HF.

14. The etching method of 13 further comprises,
forming platinum with a first thickness on the silicon substrate before forming nickel on the silicon substrate,
wherein forming nickel on the silicon substrate comprises forming nickel with a second thickness on the platinum,
wherein the first thickness is ⅙ to 1/7 of the second thickness.

15. The etching method of 13 comprises,
removing the metal catalyst remaining on the silicon substrate after etching the silicon substrate.

16. An etching method comprising:
forming a metal catalyst containing nickel on a silicon substrate, wherein a thickness of the nickel is 3 nm or less, and
selectively etching the silicon substrate in contact with the metal catalyst through chemical etching of the metal catalyst.

17. The etching method of 16, wherein the nickel has a thickness of 1 nm to 2 nm.
